(19) United States
(12) Patent Application Publication
(10) Pub. No.: US 2011/0233538 A1
(43) Pub. Date: Sep. 29, 2011

(54) COMPOUND SEMICONDUCTOR DEVICE

(75) Inventors: Shinichi Iwakami, Niiza-shi (JP); Keiichi Ichimaru, Niiza-shi (JP); Nobuo Kaneko, Niiza-shi (JP); Masahiro Niizato, Niiza-shi (JP)

(73) Assignee: Sanken Electric Co., Ltd., Niiza-shi (JP)

(21) Appl. No.: 13/033,042

(22) Filed: Feb. 23, 2011

(30) Foreign Application Priority Data
Mar. 24, 2010 (JP) 2010-067678

(51) Int. Cl. H01L 29/02

(52) U.S. Cl. 257/43; 257/E29.002

(57) ABSTRACT

A compound semiconductor device includes a compound semiconductor layer in which a two-dimensional carrier gas layer is formed, the compound semiconductor layer including a carrier travel layer and a carrier supply layer; first and second main electrodes, which are arranged apart from each other on the compound semiconductor layer, and are ohmically connected to the two-dimensional carrier gas layer; a metal oxide semiconductor film arranged on the compound semiconductor layer between the first main electrode and the second main electrode; and a control electrode arranged on the metal oxide semiconductor film, the control electrode including a titanium film that contacts the metal oxide semiconductor film or a titanium-containing compound film that contacts the metal oxide semiconductor film.

### CROSS REFERENCE TO RELATED APPLICATIONS AND INCORPORATION BY REFERENCE

This application is based upon and claims the benefit of priority from prior Japanese Patent Application P2010-067678 filed on Mar. 24, 2010; the entire contents of which are incorporated by reference herein.

### BACKGROUND OF THE INVENTION

1. Field of the Invention

The present invention relates to a compound semiconductor device, and particularly relates to a compound semiconductor device having a two-dimensional carrier gas layer.

2. Description of the Related Art

A high electron mobility transistor (HEMT) is formed by stacking a carrier travel layer and a carrier supply layer, which are made of nitride semiconductors such as gallium nitride (GaN), on each other. In the HEMT, a two-dimensional carrier gas layer is formed in the carrier travel layer located in the vicinity of a hetero junction interface between the carrier travel layer and the carrier supply layer. This two-dimensional carrier gas layer functions as a current passage (channel) between the source electrode and the drain electrode, and a current flowing through the channel is controlled by a gate control voltage applied to a gate electrode.

In general, the HEMT has characteristics in which the current flows between the source electrode and the drain electrode in a state (normal state) where the gate control voltage is not applied to the gate electrode, that is, has normally-on characteristics. Hence, in order to turn the HEMT to an off-state, it is necessary to set the gate voltage at a negative potential. Specifically, a power supply that supplies a negative voltage to be applied to the gate electrode is necessary, and an electric circuit becomes expensive.

Therefore, a variety of methods have been proposed in order to realize a HEMT having characteristics in which the current does not flow between the source electrode and the drain electrode in the normal state, that is, having normally-off characteristics. For example, there have been proposed a method of foaming a gate structure into a recess type, a method of arranging a metal oxide semiconductor film between a gate electrode with a Ni/Au/Ti structure and the two-dimensional carrier gas layer, and the like.

In the case of using the HEMT as a power semiconductor that composes the electric circuit, a higher threshold voltage is required in order to prevent a malfunction of the HEMT owing to external noise and the like.

### SUMMARY OF THE INVENTION

An aspect of the present invention is a compound semiconductor device. The compound semiconductor device includes a compound semiconductor layer in which a two-dimensional carrier gas layer is formed, the compound semiconductor layer including a carrier travel layer and a carrier supply layer; first and second main electrodes, which are arranged apart from each other on the compound semiconductor layer, and are ohmically connected to the two-dimensional carrier gas layer; a metal oxide semiconductor film arranged on the compound semiconductor layer between the first main electrode and the second main electrode; and a control electrode arranged on the metal oxide semiconductor film, the control electrode including a titanium film that contacts the metal oxide semiconductor film or a titanium-containing compound film that contacts the metal oxide semiconductor film.

### BRIEF DESCRIPTION OF THE DRAWINGS

FIG. 1 is a schematic cross-sectional view showing a configuration of a compound semiconductor device according to an embodiment of the present invention.

FIG. 2 is a schematic cross-sectional view showing a configuration example of a compound semiconductor layer of the compound semiconductor device according to the embodiment of the present invention.

FIGS. 3A to 3C are energy band diagrams for explaining characteristics of the compound semiconductor device according to the embodiment of the present invention.

FIG. 4 is Vds-Ig characteristics for explaining the characteristics of the compound semiconductor device according to the embodiment of the present invention.

FIG. 5 is a schematic cross-sectional view showing another configuration of the compound semiconductor device according to the embodiment of the present invention.

FIGS. 6 to 9 are process cross-sectional views for explaining a manufacturing method of the compound semiconductor device according to the embodiment of the present invention.

FIG. 10 is a schematic cross sectional view showing still another configuration of the compound semiconductor device according to the embodiment of the present invention.

FIGS. 11A to 11D are schematic cross-sectional views of gate electrode structures used in an experiment showing the characteristics of the compound semiconductor device according to the embodiment of the present invention.

FIG. 12 is Vgs-Ids characteristics of compound semiconductor devices using the gate electrode structures shown in FIGS. 11A to 11D.

FIG. 13 is Vgs-Ig characteristics of the compound semiconductor devices using the gate electrode structures shown in FIGS. 11A to 11D.

FIG. 14 is a schematic cross-sectional view showing a configuration of a compound semiconductor device according to a modification example of the embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

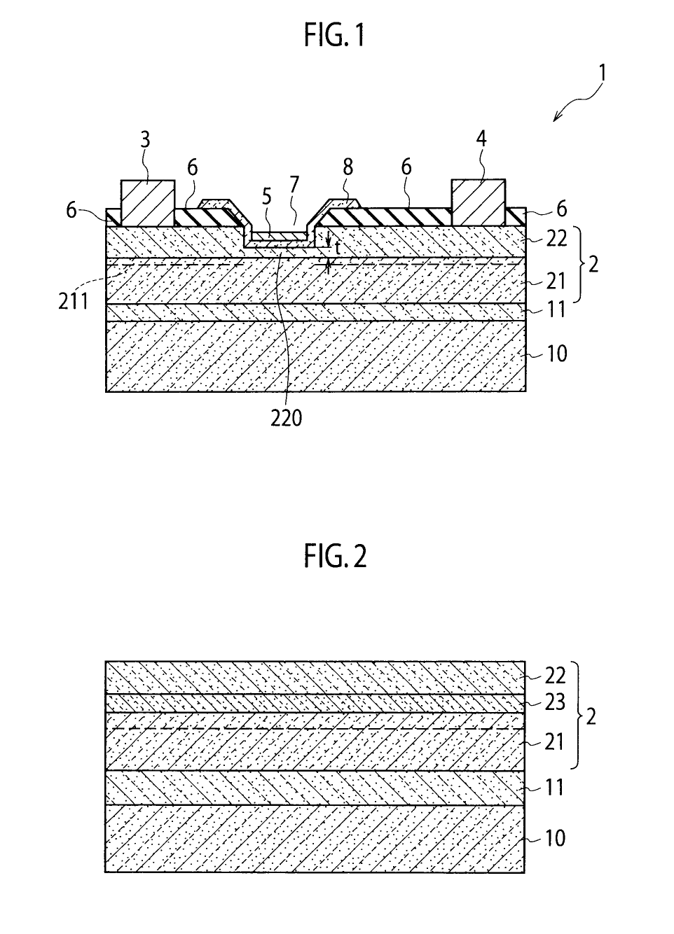

As shown in FIG. 1, a compound semiconductor device 1 according to an embodiment of the present invention includes: a compound semiconductor layer 2 having a carrier supply layer 22 and a carrier travel layer 21, in which a two-dimensional carrier gas layer 211 is formed; a first main electrode 3 and a second main electrode 4, which are arranged apart from each other on the compound semiconductor layer 2, and are ohmically connected to the two-dimensional carrier gas layer 211; a metal oxide semiconductor film 8 arranged on the compound semiconductor layer 2 between the first main electrode 3 and the second main electrode 4; and a control electrode 5 that is arranged on the metal oxide semiconductor film 8 and includes a titanium film or a film containing a titanium, which contacts the metal oxide semiconductor film 8.

A description is made below of the compound semiconductor device 1, in which the first main electrode 3 is a source electrode, the second main electrode 4 is a drain electrode, and the control electrode 5 is a gate electrode.

For a substrate 10 shown in FIG. 1, there are adoptable: a semiconductor substrate such as a silicon (Si) substrate, a silicon carbide (SiC) substrate and a gallium nitride (GaN) substrate; and an insulating substrate such as a sapphire substrate and a ceramic substrate. For example, the silicon substrate easy to increase a diameter thereof is adopted for the substrate 10, whereby manufacturing cost of the compound semiconductor device 1 can be reduced.

A buffer layer 11 can be formed by an epitaxial growth method such as well-known metal organic chemical vapor deposition (MOCVD). Although the buffer layer 11 is illustrated as one layer in FIG. 1, the buffer layer 11 may be foamed of a plurality of layers. For example, the buffer layer 11 may be formed into a buffer with a multi-layer structure, which is formed by alternately stacking a first sub-layer made of aluminum nitride (AlN) and a second sub-layer made of gallium nitride (GaN) on each other. Moreover, in the case where the compound semiconductor device 1 operates as a HEMT, the buffer layer 11 may be omitted since the buffer layer 11 is not directly concerned with such an operation of the HEMT. Furthermore, as a material of the buffer layer 11, a nitride semiconductor other than AlN and GaN or a group III-V compound semiconductor may be adopted. A structure in which the substrate 10 and the buffer layer 11 are combined with each other can also be regarded as a substrate. A structure and arrangement of the buffer layer 11 are decided in response to a material of the substrate 10, and the like.

The compound semiconductor layer 2 has a structure in which the carrier travel layer 21 and the carrier supply layer 22, each being made of a nitride compound semiconductor, are stacked in this order. As shown in FIG. 1, in the carrier travel layer 21 located in the vicinity of a hetero junction interface between the carrier travel layer 21 and the carrier supply layer 22, a two-dimensional carrier gas layer 211 as a current passage (channel) is formed.

An illustrative description is made below of the case where carriers supplied by the carrier supply layer 22 to the carrier travel layer 21 are electrons. Specifically, the two-dimensional carrier gas layer 211 is a two-dimensional electron gas (2DEG) layer, and when the compound semiconductor device 1 is turned on, the electrons are supplied from the source electrode 3 through the 2DEG layer 211 to the drain electrode 4.

The carrier travel layer 21 arranged on the buffer layer 11 is formed by epitaxially growing, for example, undoped GaN, which are not added with impurities, to a thickness of approximately 0.3 to 10 μm by an MOCVD method and the like.

The carrier supply layer 22 arranged on the carrier travel layer 21 is made of a nitride semiconductor having a band gap larger than that of the carrier travel layer 21 and a lattice constant different from that of the carrier travel layer 21. The carrier supply layer 22 is a nitride semiconductor, for example, represented by AlₓM_{y}Ga_{1-x-y}N (0≦x<1, 0≦y<1, 0≦x+y≦1, M is indium (In), boron (B) or the like), or is other compound semiconductors. In the case where the carrier supply layer 22 is AlₓM_{y}Ga_{1-x-y}N, a composition ratio x is preferably 0.1 to 0.4, more preferably, 0.3. Moreover, undoped AlₓGa₁₋ₓN is also adoptable as the carrier supply layer 22. Furthermore, a nitride semiconductor made of AlₓGa₁₋ₓN added with n-type impurities is also adoptable as the carrier supply layer 22.

The carrier supply layer 22 is formed on the carrier travel layer 21 by the epitaxial growth by the MOCVD method and the like. The carrier supply layer 22 and the carrier travel layer 21 are different in lattice constant from each other, and accordingly, piezoelectric polarization owing to lattice distortion occurs therebetween. High-density carriers are generated in the vicinity of the hetero junction by this piezoelectric polarization and spontaneous polarization inherent in crystals of the carrier supply layer 22, and the 2DEG layer 211 is formed. A film thickness of the carrier supply layer 22 is set so that the 2DEG layer 211 can be generated by the hetero junction between the carrier travel layer 21 and the carrier supply layer 22. Specifically, the film thickness of the carrier supply layer 22 is thinner than that of the carrier travel layer 21, approximately ranges from 10 to 50 nm, and for example, is approximately 25 nm.

Note that AlₓGa₁₋ₓN added with the n-type impurities may be adopted as the carrier supply layer 22, a spacer layer made of undoped AlN may be arranged between this carrier supply layer 22 and the carrier travel layer 21 made of GaN, and a contact layer made, for example, of n-type GaN may be arranged between the carrier supply layer 22 and the source and drain electrodes 3 and 4. A spacer layer 23 illustrated in FIG. 2 has an effect of suppressing the impurities and the elements from being diffused from the carrier supply layer 22 into the carrier travel layer 21. In such a way, carrier mobility in the 2DEG layer 211 is suppressed from being decreased. The contact layer contributes to reduction of a contact resistance between the compound semiconductor layer 2 and the source and drain electrodes 3 and 4.

As shown in FIG. 1, a part of an upper surface of the carrier supply layer 22 is etched, and a recessed portion (recess) 7 is formed. The recessed portion 7 is formed so that a depth thereof can be shallower than the thickness of the carrier supply layer 22. Therefore, a part of the carrier supply layer 22 remains between a bottom surface of the recessed portion 7 and the carrier travel layer 21. Hence, a thickness t of a region (hereinafter, referred to as a “remaining region”) 220 of the carrier supply layer 22, which is located below the recessed portion 7, is thinner than that of the other region of the carrier supply layer 22. The thickness t of the remaining region 220 approximately ranges from 5 to 20 nm.

Between the gate electrode 5 and the source electrode 3, and between the gate electrode 5 and the drain electrode 4, an insulating film 6 is arranged on an upper surface of the compound semiconductor layer 2. The metal oxide semiconductor film 8, the source electrode 3 and the drain electrode 4 are in contact with the compound semiconductor layer 2 at opening portions individually formed in the insulating film 6.

For the insulating film 6, there is adoptable a silicon oxide (SiO₂) film, a silicon nitride (SiN) film or a structure formed by stacking these films on each other, which has a thickness approximately ranging from 300 to 700 nm (for example, 500 nm). The insulating film 6 is not arranged in the recessed portion 7, and the insulating film 6 has an opening portion corresponding to the recessed portion 7. The surface of the compound semiconductor layer 2 is passively coated with the insulating film 6, whereby a surface level (trap) thereof is reduced, and an influence of a current collapse phenomenon can be absorbed.

Note that, preferably, the insulating film 6 is formed by a plasma chemical vapor deposition (p-CVD) method. It is also possible to form the insulating film 6 by methods other than the p-CVD method. However, in order to reduce the surface level of the compound semiconductor layer 2 and to absorb the influence of the current collapse phenomenon, it is suitable to use the p-CVD method that can suppress crystal damage on the surface of the compound semiconductor layer 2.

The metal oxide semiconductor film 8 is arranged so as to cover an inner wall of the recessed portion 7 formed on the surface of the carrier supply layer 22. In the example shown in FIG. 1, the metal oxide semiconductor film 8 is arranged so as to also cover the insulating film 6 on the periphery of the recessed portion 7. The metal oxide semiconductor film 8 may be arranged only in an inside of the recessed portion 7 so as not to be extended onto the insulating film 6.

The metal oxide semiconductor film 8 has larger electrical resistivity than the carrier supply layer 22, and is formed of a metal oxide semiconductor material having the p-polarity in the case where the two-dimensional carrier gas layer 211 is the 2DEG layer. A thickness of the metal oxide semiconductor film 8 ranges from 3 to 1000 nm, preferably ranges from 10 to 500 nm. In the case where the metal oxide semiconductor film 8 is thinner than 3 nm, the normally-off characteristics cannot be favorably obtained. Meanwhile, in the case where the metal oxide semiconductor film 8 is thicker than 1000 nm, the turn-on characteristics by the gate electrode 5 are deteriorated.

For example, the metal oxide semiconductor film 8 is formed of nickel oxide (NiO) with a thickness of 200 nm. The metal oxide semiconductor film 8 formed by sputtering NiO in an atmosphere containing oxygen has a higher hole concentration than a GaN film added with p-type impurities, and has relatively large resistivity. Therefore, the p-type metal oxide semiconductor film 8 highly raises a potential of the compound semiconductor layer 2 located below the gate electrode 5, and inhibits the 2DEG layer 211 from being formed in the carrier travel layer 21 located below the gate electrode 5. In such a way, for the compound semiconductor device 1, good normally-off characteristics can be realized. Moreover, the metal oxide semiconductor film 8 contributes to reduction of a gate leak current (leakage current) at the time of a HEMT operation of the compound semiconductor device 1.

Note that, besides NiO, the metal oxide semiconductor film 8 may be formed of any of iron oxide (FeOx), cobalt oxide (CoOx), manganese oxide (MnOx), copper oxide (CuOx) (x: arbitrary numeric value). Moreover, the metal oxide semiconductor film 8 may be formed by stacking these metal oxide films on one another.

In the opening portions formed in the insulating film 6, the source electrode 3 and the drain electrode 4 are arranged on the compound semiconductor layer 2. The source electrode 3 and the drain electrode 4 are formed of metal capable of low resistance contact (ohmic contact) with the compound semiconductor layer 2. For example, the source electrode 3 and the drain electrode 4 are formed of stacked bodies of titanium (Ti) and aluminum (Al), and the like.

The carrier supply layer 22 of the compound semiconductor layer 2 is extremely thin, and accordingly, resistance of the carrier supply layer 22 in a thickness direction is as small as ignorable. Hence, the source electrode 3 and the drain electrode 4 are in ohmic contact with the 2DEG layer 211.

The gate electrode 5 is arranged on the metal oxide semiconductor film 8 in the inside of the recessed portion 7. The gate electrode 5 is made, for example, of a stacked structure of a titanium (Ti) film and an aluminum (Al) film. Specifically, the Ti film is arranged in contact with the metal oxide semiconductor film 8, and the Al film is arranged on the Ti film, whereby the gate electrode 5 is formed.

Note that a portion of the gate electrode 5, which is in contact with the metal oxide semiconductor film 8, may be, in place of the Ti film, a compound containing Ti, such as titanium nitride (TiN), a titanium oxide nitride (TiON), and the like.

In the compound semiconductor device 1 described above, at the normal time when the gate control voltage is not applied to the gate electrode 5 (that is, at the time when the gate control voltage is 0V), a current does not flow between the source electrode 3 and the drain electrode 4 even if a potential of the drain electrode 4 is higher than a potential of the source electrode 3. Specifically, the compound semiconductor device 1 is in an off-state. A description is made below that the compound semiconductor device 1 has the normally-off characteristics.

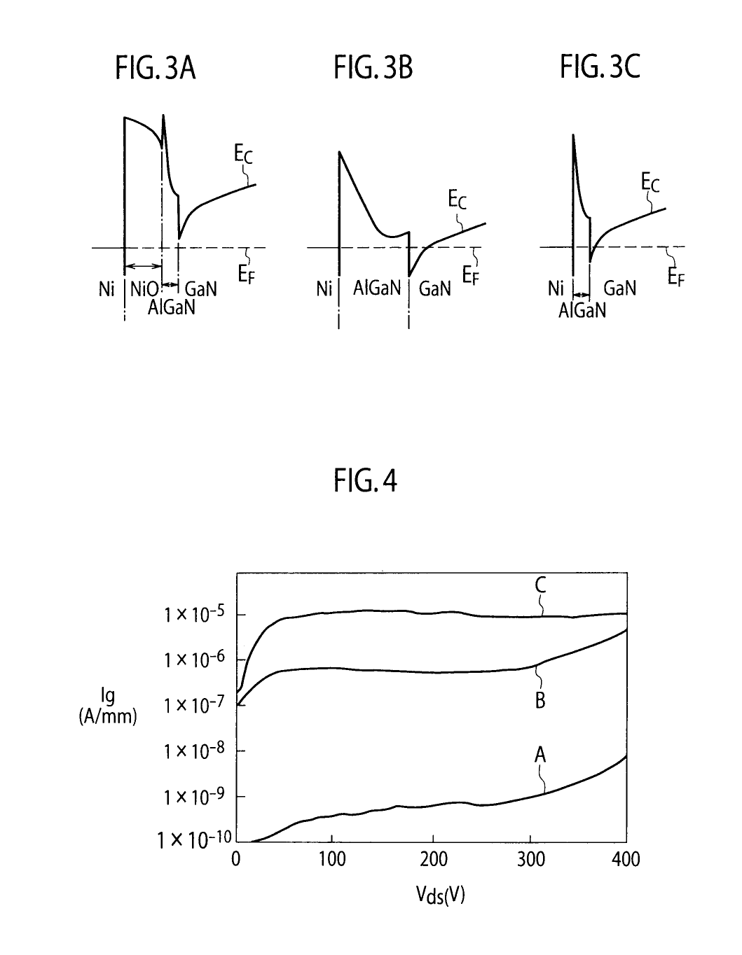

FIG. 3A to FIG. 3C show examples of energy band diagrams of HEMTs, each of which includes: a compound semiconductor layer in which a two-dimensional carrier gas layer is formed; and a gate electrode. FIG. 3A is an energy band diagram of a recessed portion of a HEMT having a similar structure to that of the compound semiconductor device 1 shown in FIG. 1. Specifically, FIG. 3A is an energy band diagram of a HEMT (hereinafter, referred to as a “HEMT-a”) in which a metal oxide semiconductor film is arranged between the compound semiconductor layer and the gate electrode arranged in the recessed portion. FIG. 3B is an energy band diagram of a HEMT (hereinafter, referred to as a “HEMT-b”) having a Schottky structure in which the gate electrode is arranged on the compound semiconductor layer. FIG. 3C is an energy band diagram of a HEMT (hereinafter, referred to as a “HEMT-c”) having a Schottky structure in which the gate electrode is arranged in the recessed portion formed on the surface of the compound semiconductor layer. Specifically, FIG. 3C is an energy band diagram of a HEMT having a structure in which the metal oxide semiconductor film 8 is removed from the compound semiconductor device 1.

In FIG. 3A to FIG. 3C, reference symbol E_{F} denotes a Fermi level, and reference symbol E_{C} denotes a level of a boundary between a conduction band and a forbidden band. Moreover, reference symbol Ni denotes the gate electrode, reference symbol NiO denotes the metal oxide semiconductor film, reference symbol AlGaN denotes the electron supply layer, and GaN denotes the electron transit layer.

In each of the HEMT-a and the HEMT-c, the recessed portion is formed on the surface of the compound semiconductor layer, and accordingly, the electron supply layer located below the gate electrode is thin (for example, 5 nm or less). Therefore, lattice relaxation occurs in the electron supply layer located below the gate electrode, and charges resulting from the piezoelectric polarization are reduced, and in addition, characteristics of the bulk are weakened, and charges resulting from the spontaneous polarization are also reduced. By such reduction of these charges in the electron supply layer, the Fermi level is lowered. Therefore, as shown in FIG. 3A and FIG. 3C, the potential below the gate electrode rises relatively in comparison with FIG. 3B.

In the HEMT-a, the metal oxide semiconductor film 8 is arranged, and accordingly, the potential below the gate electrode is further raised as shown in FIG. 3A. As a result, the 2DEG layer is not formed on the electron transit layer located below the gate electrode, and the HEMT having the normally-off characteristics is obtained. In other words, at the time when the compound semiconductor device 1 is turned off, the polarization in the remaining region 220 of the carrier supply layer 22, which is located below the recessed portion 7, is cancelled by the metal oxide semiconductor film 8, and the 2DEG layer 211 is not formed in the carrier travel layer 21 located below the gate electrode 5. Specifically, the 2DEG layer 211 is divided, and accordingly, a current does not flow between the source electrode 3 and the drain electrode 4.

Meanwhile, when a positive gate control voltage higher than a threshold voltage is applied between the gate electrode 5 and the source electrode 3 in a state where the potential of the drain electrode 4 is higher than the potential of the source electrode 3, a channel is formed in the carrier travel layer 21 located below the gate electrode 5 by a principle similar to that of formation of a channel (current passage) in the well-known MOS gate structure. Specifically, when a predetermined gate control voltage is applied to the gate electrode 5, then the polarization occurs in the metal oxide semiconductor film 8, and holes concentrate on the carrier supply layer 22 side of the metal oxide semiconductor film 8. Therefore, electrons are induced on the side of the carrier travel layer 21, which is in contact with the carrier supply layer 22, and a channel is formed. In such a way, the compound semiconductor device 1 is turned to an on-state, and the electrons flow through a route formed of the source electrode 3, the carrier supply layer 22, the 2DEG layer 211, the channel, the 2DEG layer 211, the carrier supply layer 22 and the drain electrode 4 in this order.

FIG. 4 shows a relationship between the inter-drain/source voltage Vds and the gate leak current (leakage current) Ig in each of the HEMT-a, the HEMT-b and the HEMT-c. A characteristic line A indicates Vds-Ig characteristics of the HEMT-a, a characteristic line B indicates Vds-Ig characteristics of the HEMT-b, and a characteristic line C indicates Vds-Ig characteristics of the HEMT-c. The gate leak current Ig in each of the characteristic lines A to C is a gate leak current in the case where the gate electrode and the source electrode are at an equal potential.

As apparent from comparison among the characteristic lines A to C, the gate leak current Ig of the HEMT-a in which the metal oxide semiconductor film 8 is arranged is vastly smaller than the gate leak currents Ig of the HEMT-b and the HEMT-c, each of which does not have the metal oxide semiconductor film 8.

As described above, in accordance with the compound semiconductor device 1, which has such a recess-type gate structure, and has the metal oxide semiconductor film 8 arranged between the compound semiconductor layer 2 and the gate electrode 5, good normally-off characteristics in which the threshold voltage is high can be realized, and simultaneously therewith, the gate leak current can be reduced.

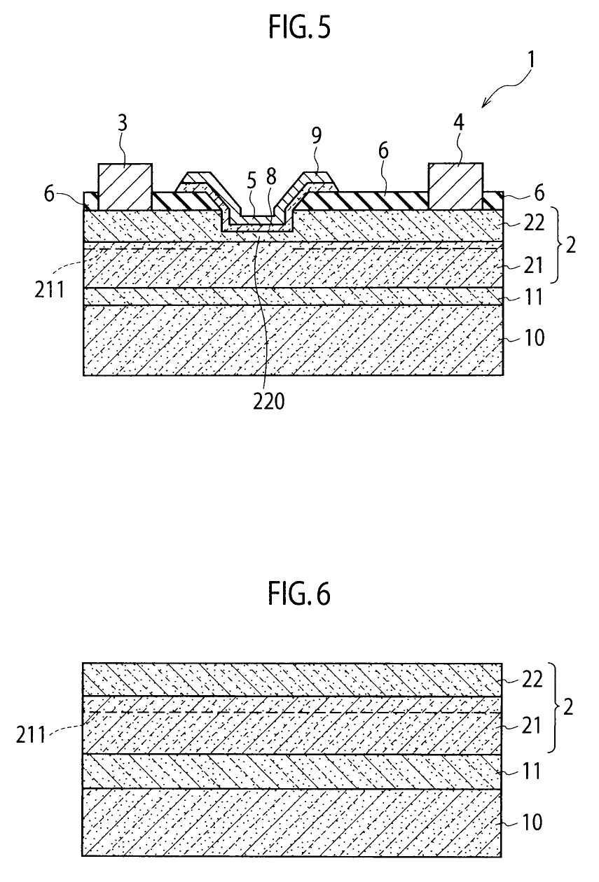

Moreover, as shown in FIG. 5, a field plate 9 may be arranged on the insulating film 6. The field plate 9 is electrically connected to the gate electrode 5, and is formed continuously with the gate electrode 5. As shown in FIG. 5, the field plate 9 is opposed to the surface of the carrier supply layer 22 while sandwiching the insulating film 6 and the metal oxide semiconductor film 8 therebetween.

With regard to the opening portion of the insulating film 6 on the periphery of the recessed portion 7, a wall surface thereof has an inclination approximately ranging from 50 to 60° with respect to the surface of the compound semiconductor layer 2. Therefore, an interval between the field plate 9 and the carrier supply layer 22 is gradually increased with distance from the gate electrode 5 arranged in the recessed portion 7. In such a way, electric field concentration at an end portion of the gate electrode 5 can be favorably absorbed. In such a way, a withstand voltage of the compound semiconductor device 1 can be enhanced.

Moreover, the electrons trapped at the surface level of the compound semiconductor layer 2 when a reverse voltage is applied between the drain electrode 4 and the source electrode 3 can be extracted to the gate electrode 5 through the field plate 9. In such a way, the influence of the current collapse phenomenon can be absorbed.

A description is made below of a manufacturing method of the compound semiconductor device according to the embodiment of the present invention with reference to FIG. 6 to FIG. 9. Note that, naturally, the manufacturing method of the compound semiconductor device, which is described below, is an example, and is realizable by other various manufacturing methods including modification examples thereof. An illustrative description is made below of the case of manufacturing the compound semiconductor device 1 shown in FIG. 5.

(A) As shown in FIG. 6, the buffer layer 11, the carrier travel layer 21 and the carrier supply layer 22 are epitaxially grown in this order on the substrate 10 by the MOCVD method and the like. The buffer layer 11 has a structure, for example, in which the AlN layer and the GaN layer are alternately stacked on each other. The carrier travel layer 21 is, for example, an undoped GaN film. The carrier supply layer 22 is made of a nitride semiconductor having a band gap larger than that of the carrier travel layer 21 and a lattice constant different from that of the carrier travel layer 21. For example, an undoped AlGaN film is adoptable as the carrier supply layer 22.

(B) On the carrier supply layer 22, the insulating film 6, which is, for example, the SiO₂ film, the SiN film or the structure formed by stacking these films on each other, is formed by the plasma chemical vapor deposition (p-CVD) method and the like. Note that, as a cap layer for controlling surface charges, an undoped or n-type GaN film may be formed between the carrier supply layer 22 and the insulating film 6.

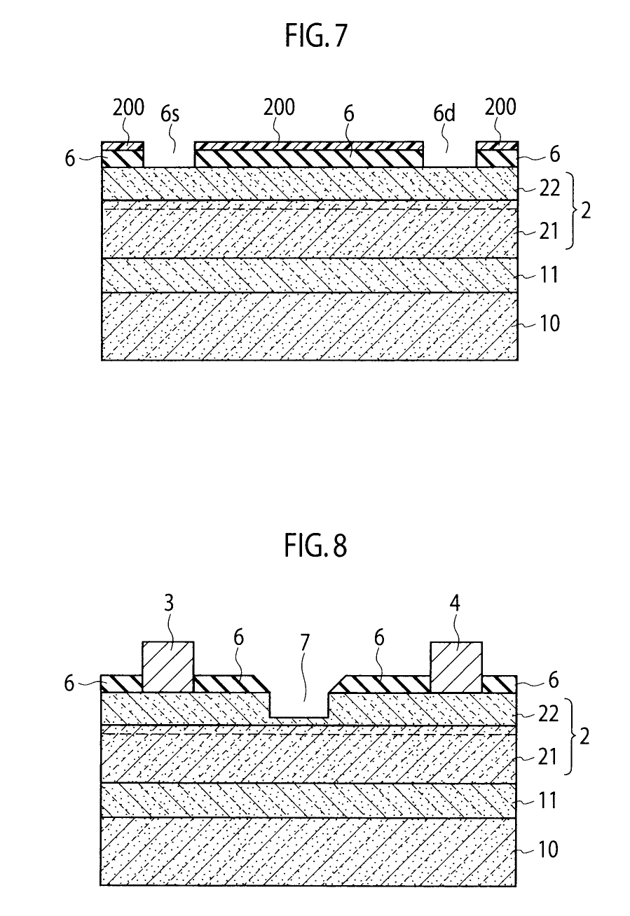

(C) As shown in FIG. 7, opening portions 6s and 6d are formed at predetermined positions of the insulating film 6 by using a photolithography technology. Specifically, the insulating film 6 at positions where the source electrode 3 and the drain electrode 4 are to be arranged is removed by etching by using a photoresist film 200 as a mask. At this time, the carrier supply layer 22 at the opening portions 6s and 6d of the insulating film 6 may be etched until the surface of the carrier travel layer 21 is exposed.

(D) After removing the photoresist film 200, a stacked film made of a Ti film with a film thickness of approximately 25 nm and an Al film with a film thickness of approximately 300 nm is formed on the insulating film 6 by a sputtering method so as to fill the opening portions 6s and 6d. Thereafter, a part of the stacked film of the Ti film and the Al film is removed by etching by using the photolithography technology. In such a way, the source electrode 3 and the drain electrode 4, each having the structure in which the Ti film and the Al film are stacked on each other, are formed.

(E) Ohmic sintering is performed so that the source electrode 3 and the drain electrode 4 can be brought into low resistance contact with the 2DEG layer 211.

(F) The insulating film 6 and an upper portion of the carrier supply layer 22 are partially and selectively removed by etching by using the photolithography technology, and the recessed portion 7 is formed as shown in FIG. 8. At this time, an etching amount for the carrier supply layer 22 is adjusted so that the thickness t of the remaining region 200 can range from 5 to 20 nm.

(G) By the sputtering method, a NiO film 80 with a film thickness of approximately 200 nm is formed on the carrier supply layer 22 and the insulating film 6 so as to cover the inner wall of the recessed portion 7. The NiO film 80 is a material of the p-type metal oxide semiconductor film 8. After forming the NiO film 80, ions of oxygen (O₂) may be implanted into the NiO film 80.

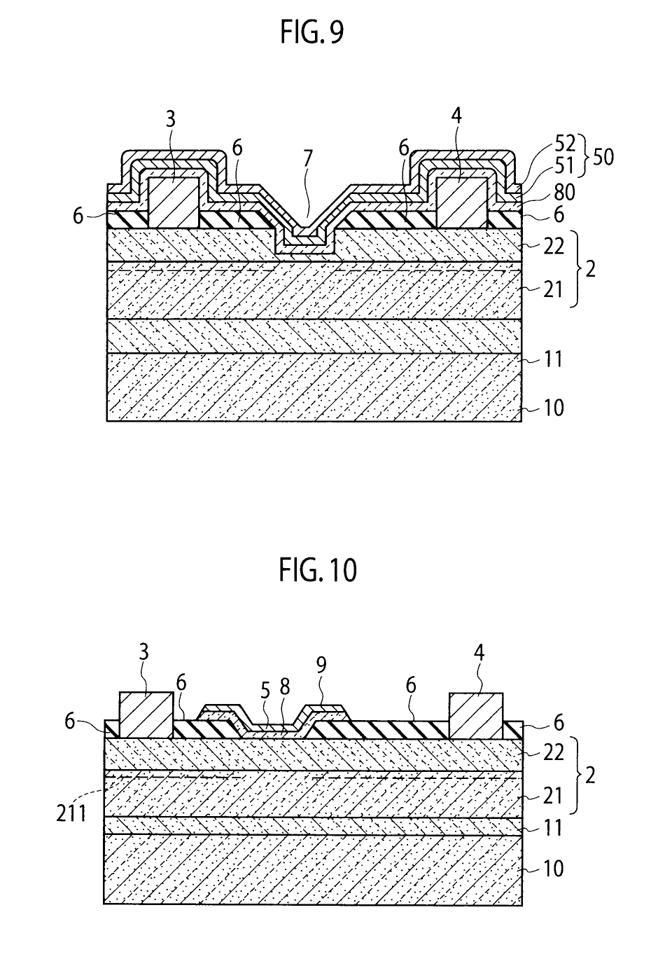

(H) On the NiO film 80, a TiN film 51 with a film thickness of approximately 100 nm is formed by the sputtering method. Moreover, on the TiN film, an Al film 52 with a film thickness of approximately 200 nm is foamed by the sputtering method. In such a way, as shown in FIG. 9, a conductor layer 50 formed by stacking the TiN film 51 and the Al film 52 on each other is formed on the NiO film 80. Note that an AlCu film may be used in place of the Al film.

(I) By using the photolithography technology, the conductor layer 50 and the NiO film 80 are partially removed, and there are formed: the gate electrode 5 having the structure in which the TiN film 51 and the Al film 52 are stacked on each other; the field plate 9; and the metal oxide semiconductor film 8 made of the NiO film.

Although not shown in FIG. 5, a protection film may be formed by the CVD method and the like on the insulating film 6, the source electrode 3, the drain electrode 4 and the gate electrode 5. The protection film is, for example, a SiO₂ film. In such a manner as described above, the compound semiconductor device 1 shown in FIG. 5 is obtained.

The p-type metal oxide semiconductor film 8 is made, for example, of a NiO film formed by magnetron sputtering. Specifically, the substrate 10 on which the compound semiconductor layer 2 and the insulating film 6 are formed is housed in a magnetron sputtering apparatus. Then, an inside of the magnetron sputtering apparatus is turned to an atmosphere containing oxygen (preferably, an atmosphere containing mixed gas of argon and oxygen), and NiO is sputtered, whereby the metal oxide semiconductor film 8 is formed. NiO is sputtered in the atmosphere containing oxygen, whereby the p-type metal oxide semiconductor film 8 having a high hole concentration can be easily formed.

The description has been made above of the example of performing the patterning for the metal oxide semiconductor film 8 simultaneously with the patterning for the field plate and the gate electrode 5. However, the metal oxide semiconductor film 8 may be patterned in an independent step. Moreover, such structures as described above may be formed in a lift-off process.

As already described, besides NiO, the metal oxide semiconductor film 8 may be formed of any of iron oxide, cobalt oxide, manganese oxide, copper oxide and the like, or formed by stacking films of these metal oxides on one another. It is preferable that the metal oxide semiconductor film 8 made of these metal oxides also be formed by sputtering such metal materials in the atmosphere containing oxygen.

Moreover, besides such a method of sputtering the metal materials in the atmosphere containing oxygen, the metal oxide semiconductor film 8 may be formed in such a manner that the metal film is formed by the sputtering and the like, and is thereafter oxidized.

Note that, in order to intensify the p-type characteristics of the metal oxide semiconductor film 8, the metal oxide semiconductor film 8 can be subjected to heat treatment, ozone ashing treatment, or oxygen ashing.

In the compound semiconductor device 1 shown in FIG. 1, the recessed portion 7 is formed on the upper surface of the carrier supply layer 22. However, in the case where the good normally-off characteristics are obtained even if the recessed portion 7 is not formed, then as shown in FIG. 10, the metal oxide semiconductor film 8 may be formed on a flat surface of the carrier supply layer 22 without forming the recessed portion 7. Also in such a compound semiconductor device 1, which is shown in FIG. 10, and does not adopt the recess-type gate structure, the threshold voltage can be raised by the fact that the metal oxide semiconductor film 8 is arranged between the gate electrode 5 and the carrier supply layer 22. The recessed portion 7 is not formed, whereby a manufacturing process of the compound semiconductor device 1 can be shortened, and the gate leak current can be further reduced.

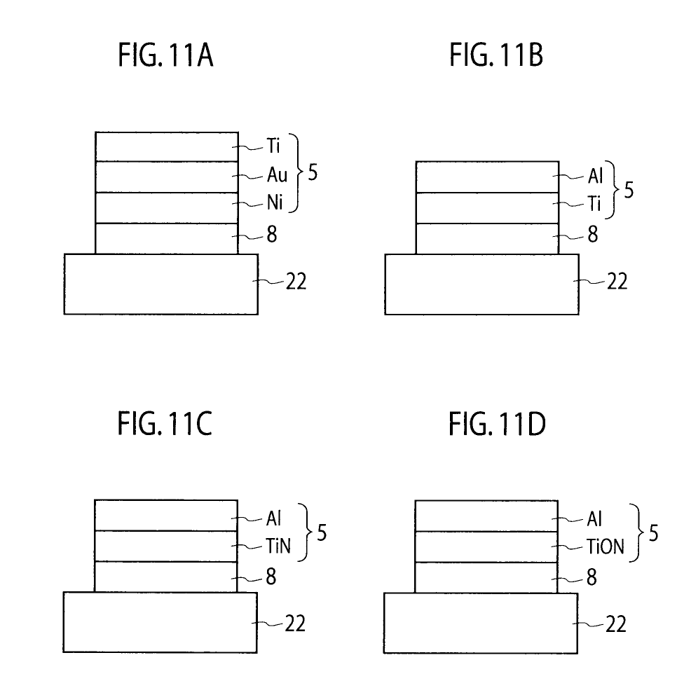

Hereinbelow, in order to describe characteristic advantages of the compound semiconductor device 1, results of an experiment are shown, which was performed by using compound semiconductor devices having HEMT structures, the compound semiconductor devices individually including gate electrodes having structures shown in FIG. 11A to FIG. 11D. FIG. 11A is an example (hereinafter, referred to as “Comparative example”) of arranging a gate electrode having a structure in which Ni/Au/Ti are stacked on one another. FIG. 11B is an example (hereinafter, referred to as “Example 1”) of arranging, on the metal oxide semiconductor film 8, the gate electrode 5 having the structure in which the Ti film and the Al film are stacked on each other. FIG. 11C is an example (hereinafter, referred to as “Example 2”) of arranging, on the metal oxide semiconductor film 8, the gate electrode 5 having the structure in which the TiN film and the Al film are stacked on each other. FIG. 11D is an example (hereinafter, referred to as “Example 3”) of arranging, on the metal oxide semiconductor film 8, the gate electrode 5 having the structure in which the TiON film and the Al film are stacked on each other. Specifically, Examples 1 to 3 are different from Comparative example in having the structure of the gate electrode 5 of the compound semiconductor device 1 according to the embodiment of the present invention, and in that the Ti film, TiN film and TiON film of the gate electrodes 5 thereof individually contact the metal oxide semiconductor films 8.

Note that, in FIG. 11A to FIG. 11D, the metal oxide semiconductor film 8 is the NiO film. Moreover, the recessed portion 7 is not formed in the carrier supply layer 22.

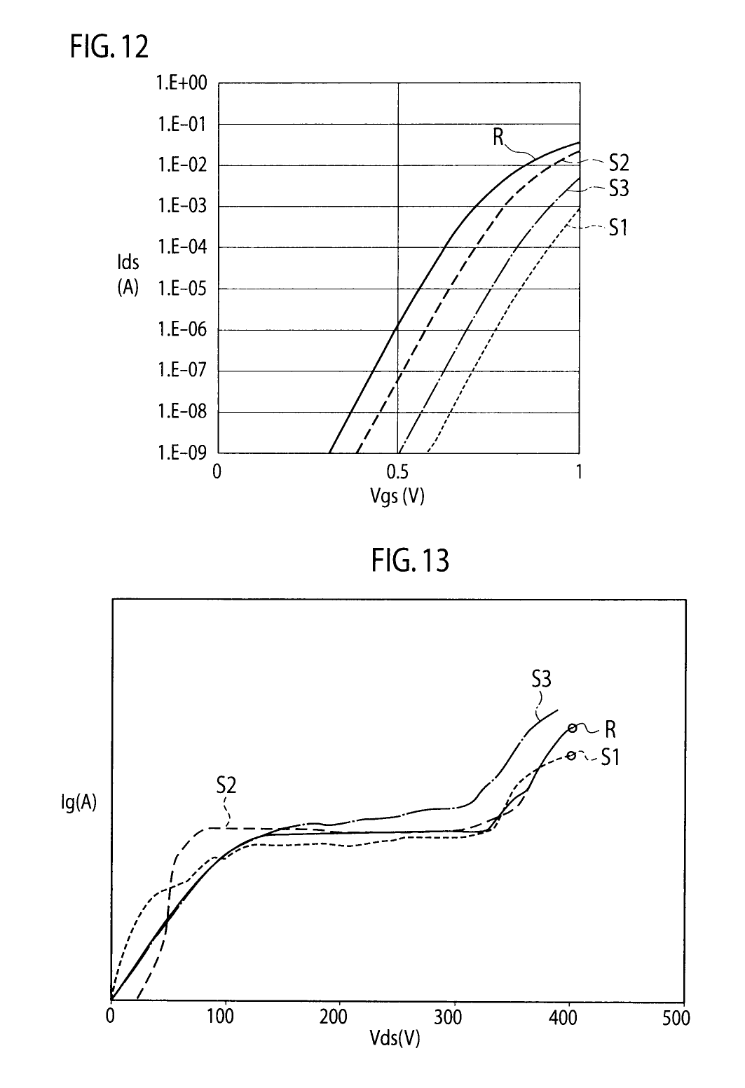

FIG. 12 shows Vgs-Ids characteristics of Comparative example and Examples 1 to 3. In FIG. 12, a characteristic line R indicates characteristics of Comparative example, and characteristic lines S1 to S3 indicate characteristics of Examples 1 to 3, respectively (hereinafter, the same will apply).

From FIG. 12, it is understood that each of Examples 1 to 3 has a threshold voltage larger than Comparative example, and that a current does not flow between the drain electrode and the source electrode unless a gate control voltage higher than in the case of Comparative example is applied. Specifically, Examples 1 to 3 in which the Ti film, TiN film or TiON film of the gate electrodes 5 individually contact the metal oxide semiconductor films 8 have better normally-off characteristics than Comparative example.

FIG. 13 shows Vgs-Ig characteristics of Comparative example and Examples 1 to 3. In accordance with FIG. 13, each of Examples 1 to 3 has a gate leak current value equivalent to that of Comparative example. Specifically, Examples 1 to 3, in which the Ti film, TiN film or TiON film of the gate electrodes 5 individually contact the metal oxide semiconductor films 8, can suppress the gate leak current in a similar way to Comparative example.

Hence, it was confirmed that, in comparison with the compound semiconductor device, in which the gate electrode having the structure in which Ni/Au/Ti are stacked on the metal compound semiconductor film 8, the compound semiconductor device according to the embodiment of the present invention, in which the Ti film of the gate electrode 5 or such a Ti-containing compound film of the gate electrode 5 contacts the metal oxide semiconductor film 8, has good normally-off characteristics with a higher threshold voltage while maintaining the effect of suppressing the gate leak current.

As described above, in the compound semiconductor device 1 according to the embodiment of the present invention, the metal oxide semiconductor film 8 having a higher hole concentration than the GaN film added with the p-type impurities is formed. For example, the p-type metal oxide semiconductor film 8 is formed by the sputtering in the atmosphere containing oxygen. Therefore, as already described, the potential below the gate electrode 5 is raised by arranging the metal oxide semiconductor film 8. In such a way, in the compound semiconductor device 1, the 2DEG layer 211 is effectively suppressed, at the normal time, from being formed in the carrier travel layer 21 located below the gate electrode 5. Moreover, the threshold voltage can be further raised in such a manner that the portion of the gate electrode 5, which is in contact with the metal oxide semiconductor film 8, is formed into the Ti film or the Ti-containing compound film (for example, the TiN film and the TiON film).

Hence, in accordance with the compound semiconductor device 1, a compound semiconductor device having good normally-off characteristics can be realized. Note that it is easy to manufacture the metal oxide semiconductor film 8 since the metal oxide semiconductor film 8 is made of a chemically stable substance, and is formed in the atmosphere containing oxygen.

Moreover, the metal oxide semiconductor film 8 has relatively high resistivity, and is formed to be relatively thick (for example, 10 to 500 nm). Therefore, the gate leak current of the compound semiconductor device 1 is reduced, and the withstand voltage of the compound semiconductor device 1 is enhanced. In such a way, reliability of the compound semiconductor device 1 is increased. Note that the threshold voltage does not shift to the negative side even if the metal oxide semiconductor film 8 is formed to be relatively thick.

As mentioned above, the normally-off characteristics of the compound semiconductor device 1 is not obtained only by adopting the recess-type gate structure, but is obtained in combination with the arrangement of the metal oxide semiconductor film 8. Hence, the thickness t of the remaining region 220 located below the gate electrode 5 can be made as relatively thick as, for example, an approximate range from 3 to 8 nm. As a result, when the gate control voltage to turn the compound semiconductor device 1 to the on-state is applied to the gate electrode 5, an electron concentration of the region of the carrier travel layer 21, which is opposed to the gate electrode 5, can be made relatively high. Therefore, on-resistance is lowered, and the maximum allowable current value of the compound semiconductor device 1 can be increased.

Moreover, the thickness of the carrier supply layer 22 can be made relatively thick (for example, 10 nm or more) between the source electrode 3 and the gate electrode 5 and between the drain electrode 4 and the gate electrode 5. In addition, a ratio of Al in the carrier supply layer 22 is 0.1 or more, which is relatively large. Therefore, though the compound semiconductor device 1 has the normally-off characteristics, the electron concentration of the 2DEG layer 211 is relatively large, and the on-resistance can be lowered.

### <Modification>

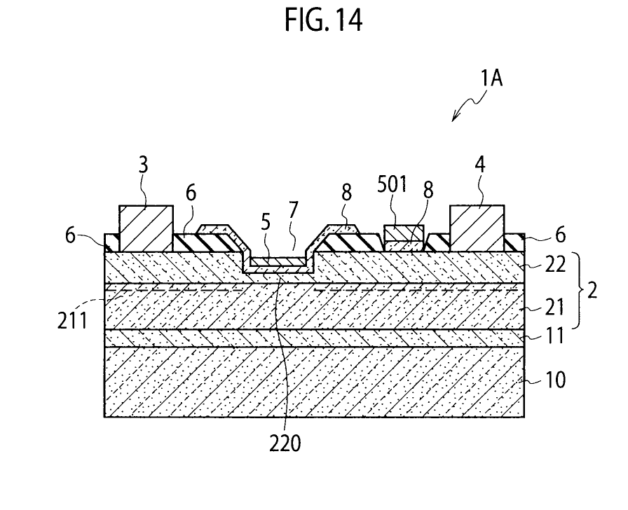

FIG. 14 shows a compound semiconductor device 1A according to a modification example of the embodiment of the present invention. The compound semiconductor device 1A is different from the compound semiconductor device 1 in including an auxiliary electrode 501 having a similar structure to that of the gate electrode 5. Other configurations are similar to those of the embodiment shown in FIG. 1.

In a similar way to the gate electrode 5, the auxiliary electrode 501 has a structure including a Ti film or a Ti-containing compound film (for example, a TiN film and a TiON film), which contacts the metal oxide semiconductor film 8. For example, the auxiliary electrode 501 can be formed simultaneously with the gate electrode 5. In an example shown in FIG. 14, between the gate electrode 5 and the drain electrode 4, the auxiliary electrode 501 is arranged on the metal oxide semiconductor film 8 formed on the carrier supply layer 22. A voltage is appropriately applied to the auxiliary electrode 501, whereby the electric field concentration between the gate electrode 5 and the drain electrode 4 can be favorably absorbed. Moreover, the auxiliary electrode 501 and the field plate 9 may be electrically connected to each other.

### Other Embodiments

In the already made description of the embodiment, the example where the carrier supply layer 22 supplies the electrons has been shown; however, the carrier supply layer 22 can be replaced by a hole supply layer made of a p-type semiconductor. In this case, a two-dimensional hole gas layer is generated as the two-dimensional carrier gas layer in the region corresponding to the 2DEG layer 211. Then, an n-type metal oxide semiconductor material is used for the metal oxide semiconductor film 8, whereby the two-dimensional carrier gas layer is not framed in the carrier travel layer 21 located below the gate electrode 5. In such a way, good normally-off characteristics are obtained for the compound semiconductor device 1.

Various modifications will become possible for those skilled in the art after receiving the teachings of the present disclosure without departing from the scope thereof.

What is claimed is:

1. A compound semiconductor device comprising:
a compound semiconductor layer in which a two-dimensional carrier gas layer is formed, the compound semiconductor layer including a carrier travel layer and a carrier supply layer;
first and second main electrodes, which are arranged apart from each other on the compound semiconductor layer, and are ohmically connected to the two-dimensional carrier gas layer;
a metal oxide semiconductor film arranged on the compound semiconductor layer between the first main electrode and the second main electrode; and
a control electrode arranged on the metal oxide semiconductor film, the control electrode including a titanium film that contacts the metal oxide semiconductor film or a titanium-containing compound film that contacts the metal oxide semiconductor film.

2. The compound semiconductor device of claim 1, wherein the titanium-containing compound film is a titanium nitride film or a titanium oxide nitride film.

3. The compound semiconductor device of claim 1, wherein the gate electrode is arranged in an inside of a recessed portion formed on an upper surface of the compound semiconductor layer at a depth insufficient to reach the carrier travel layer.

4. The compound semiconductor device of claim 1, wherein an insulating film is arranged on an upper surface of the compound semiconductor layer between the control electrode and the first and second main electrodes.

5. The compound semiconductor device of claim 4, further comprising:
a field plate arranged on the insulating film in at least a part located between the control electrode and the first and second main electrodes.

6. The compound semiconductor device of claim 1, wherein the carrier travel layer and the carrier supply layer are made of a group III nitride compound semiconductors.

7. The compound semiconductor device of claim 1, wherein the metal oxide semiconductor film is any of a nickel oxide film, an iron oxide film, a cobalt oxide film, a manganese oxide film and a copper oxide film or a stacked body of the oxide films.

8. The compound semiconductor device of claim 1, wherein the two-dimensional carrier gas layer is an electron gas layer, and the metal oxide semiconductor film is a p-type metal oxide semiconductor film.
